(19) United States
(12) Patent Application Publication
(10) Pub. No.: US 2026/0206422 A1
(43) Pub. Date: Jul. 16, 2026

(54) DISPLAY DEVICE, MANUFACTURING METHOD OF DISPLAY DEVICE, AND ELECTRONIC DEVICE INCLUDING THE DISPLAY DEVICE

(71) Applicant: Samsung Display Co., LTD., Yongin-si (KR)

(72) Inventors: HYUNGJUN LIM, Yongin-si (KR); Hyeonjin Goh, Yongin-si (KR); SEOKHWAN KIM, Yongin-si (KR)

(21) Appl. No.: 19/365,434

(22) Filed: Oct. 22, 2025

(30) Foreign Application Priority Data
Jan. 10, 2025 (KR) 10-2025-0004080

(51) Int. Cl. H10K 59/122; H10K 59/12; H10K 59/121

(52) U.S. Cl. CPC H10K 59/122; H10K 59/1201; H10K 59/1213

(57) ABSTRACT

A display device includes a substrate, a first type transistor including: a second active pattern disposed on the substrate and doped with an N-type dopant, a third gate electrode overlapping the second active pattern, and at least one of first metal patterns disposed on the third gate electrode and connected to the second active pattern through a contact hole, a light-emitting element disposed on the first metal patterns, and including a first electrode, where a pixel opening is defined by a pixel defining layer, and a second metal pattern disposed between the first metal patterns and the first electrode, and covering the third gate electrode in a plan view, where a slit is defined in the second metal pattern to overlap the pixel opening in the plan view.

This application claims priority to Korean Patent Application 10-2025-0004080, filed on January 10, 2025, and all the benefits accruing therefrom under 35 U.S.C. §119, the content of which in its entirety is herein incorporated by reference.

### BACKGROUND

### Field

The disclosure relates to a display device, a manufacturing method of the display device, and an electronic device including the display device. More specifically, the disclosure relates to a display device including an n-channel metal-oxide-semiconductor (“NMOS”) transistor, a manufacturing method of the display device, and an electronic device including the display device.

### Description of the Related Art

An user may look at an image from a front of a display screen, but the user may also look at the image from various angles. Therefore, technology that minimizes color coordinate distortion due to the viewing angles is desired to improve the quality of the image viewed from various angles.

### SUMMARY

Embodiments provide a display device with improved color symmetry without increasing a thickness of the insulating layer.

Other embodiments provide a manufacturing method of the display device.

Other embodiments provide an electronic device including the display device.

A display device according to embodiments includes: a substrate; a first type transistor including: a second active pattern disposed on the substrate and doped with an N-type dopant, a third gate electrode overlapping the second active pattern, and at least one of first metal patterns disposed on the third gate electrode and connected to the second active pattern through a contact hole; a light-emitting element disposed on the first metal patterns, and including a first electrode, where a pixel opening is defined by a pixel defining layer; and a second metal pattern disposed between the first metal patterns and the first electrode, and covering the third gate electrode in a plan view, where a slit is defined in the second metal pattern to overlap the pixel opening in the plan view.

In an embodiment, in the plan view, the pixel opening may include a first point, a second point farthest apart from the first point in a first direction, a third point which crosses the first point, a fourth point farthest apart from the third point in a second direction which crosses the first direction, a minimum distance in the first direction between the first point of the pixel opening and a nearest boundary line most adjacent to the first point in the slit and a minimum distance in the first direction between the second point and a nearest boundary line most adjacent to the second point in the slit may be equal to each other, and a minimum distance in the second direction between the third point of the pixel opening and a nearest boundary line most adjacent to the third point in the slit and a minimum distance in the second direction between the fourth point and a nearest boundary line most adjacent to the fourth point in the slit may be equal to each other.

In an embodiment, in the plan view, the slit of the second metal pattern defined at positions overlapping the pixel opening may be provided in plural.

In an embodiment, in a cross-sectional view, the first electrode may include a first end and a second end spaced apart from the first end in a first direction, and the second metal pattern may be spaced apart from both the first end and the second end.

In an embodiment, in a cross-sectional view, in the pixel opening, the second metal pattern and the at least one of the first metal patterns may be spaced apart from each other.

In an embodiment, the display device may further include a second type transistor between the substrate and the first type transistor, and the second type transistor may include a first active pattern which is doped with a P-type dopant.

In an embodiment, the second active pattern may include an oxide semiconductor, and the first active pattern may include a silicon semiconductor.

In an embodiment, the pixel opening may include a first opening of a pixel which emits a first color light, a second opening of the pixel which emits a second color light, different from the first color light, and a third opening of the pixel which emits a third color light, different from both the first and the second color lights, the second color light may be green light, and the slit may be defined to at least partially overlap the second opening in the plan view.

In an embodiment, the light-emitting element may further include an interlayer disposed on the first electrode in the pixel opening, which is defined by the pixel defining layer; and a second electrode disposed on the interlayer.

In an embodiment, the display device may further include an insulating layer disposed between the second metal pattern and the first electrode, and the insulating layer may include an organic material.

A manufacturing method of a display device according to an embodiment of the disclosure includes: forming a first type transistor on a substrate, where the first type transistor includes: a second active pattern disposed on the substrate and doped with N-type dopant, a third gate electrode overlapping the second active pattern, and at least one of first metal patterns disposed on the third gate electrode and connected to the second active pattern through a contact hole; forming a second metal pattern on the first metal patterns to cover the third gate electrode in a plan view, where a slit is formed through the second metal pattern to overlap a pixel opening in the plan view, and forming a light-emitting element on the first metal patterns, where the light-emitting element includes a first electrode, and the pixel opening is defined by a pixel defining layer.

In an embodiment, the forming the second metal patterns may include forming a second preliminary metal layer on a first via insulating layer covering the first metal patterns; and removing a portion of the second preliminary metal layer by using a photoresist to define the slit.

In an embodiment, in a cross-sectional view, the first electrode may include a first end and a second end spaced apart in the first direction from the first end, and in the removing the portion of the second preliminary metal layer, the second preliminary metal layer may be removed at positions overlapping the first end and the second end of the first electrode.

In an embodiment, in the removing the portion of the second preliminary metal layer, the second preliminary metal layer may be removed at positions overlapping the first metal patterns.

An electronic device according to an embodiment of the disclosure includes: a processor which outputs an image data signal and an input control signal; and a display device which operates based on the image data signal and the input control signal, where the display device includes: a substrate; a first type transistor including: a second active pattern disposed on the substrate and doped with an N-type dopant, a third gate electrode overlapping the second active pattern, and at least one of first metal patterns disposed on the third gate electrode and connected to the second active pattern through a contact hole; a light-emitting element disposed on the first metal patterns, and including a first electrode, where a pixel opening is defined by a pixel defining layer; and a second metal pattern disposed between the first metal patterns and the first electrode, and covering the third gate electrode a plan view, where a slit is defined in the second metal pattern to overlap the pixel opening in the plan view.

In an embodiment, in the plan view, the pixel opening may include a first point, a second point farthest apart from the first point in a first direction, a third point which crosses the first point, a fourth point farthest apart from the third point in a second direction which crosses the first direction, a minimum distance in the first direction between the first point of the pixel opening and a nearest boundary line most adjacent to the first point in the slit and a minimum distance in the first direction between the second point and a nearest boundary line most adjacent to the second point in the slit may be equal to each other, and a minimum distance in the second direction between the third point of the pixel opening and a nearest boundary line most adjacent to the third point in the slit and a minimum distance in the second direction between the fourth point and a nearest boundary line most adjacent to the fourth point in the slit may be equal to each other.

In an embodiment, in a cross-sectional view, the first electrode may include a first end and a second end spaced apart from the first end in a first direction, and the second metal pattern may be spaced apart from both the first end and the second end.

In an embodiment, in a cross-sectional view, in the pixel opening, the second metal pattern and the at least one of the first metal patterns may not overlap each other.

In an embodiment, the electronic device may further include: a second type transistor between the substrate and the first type transistor, and the second type transistor includes a first active pattern which is doped with a P-type dopant, the second active pattern includes an oxide semiconductor, and the first active pattern includes a silicon semiconductor.

In an embodiment, the pixel opening may include a first opening of a pixel which emits a first color light, a second opening of the pixel which emits a second color light, different from the first color light, and a third opening of the pixel which emits a third color light, different from both the first color light and the second color light, the second color light may be green light, and the slit may be defined to at least a partially overlap the second opening in the plan view.

In the display device and the electronic device according to embodiments of the disclosure, the slit is formed in the second metal pattern not to overlap the ends of the first electrode. Accordingly, an effect due to a taper of the second metal pattern may be minimized.

In addition, the display device and the electronic device according to embodiments of the disclosure may include the second metal pattern with the slit to have symmetry in the second metal pattern. Accordingly, color symmetry may be improved.

In addition, the display device and the electronic device according to embodiments of the disclosure may include the second metal pattern disposed not to overlap the first metal pattern. Accordingly, the effect due to the taper of the first metal pattern may be minimized.

In addition, the display device and the electronic device according to embodiments of the disclosure may include the second metal pattern with the slit defined therein not to overlap the first type transistor. The second metal pattern may shield the first type transistor and effectively prevent a change in device characteristics.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a block diagram illustrating an electronic device according to an embodiment.

FIG. 2 is a schematic diagram of an electronic device according to various embodiments.

FIG. 3 is a view illustrating an electronic device according to an embodiment.

FIG. 4 is a plan view illustrating a display device of FIG. 3.

FIG. 5 is a block diagram illustrating the display device of FIG. 3.

FIG. 6 is a circuit diagram illustrating a pixel of FIGS. 4 and 5.

FIG. 7 is a cross-sectional view illustrating an example of transistors of FIG. 6.

FIG. 8 is a cross-sectional view illustrating a second metal pattern included in the electronic device of FIG. 1.

FIGS. 9, 10, 11, 12, 13, and 14 are plan views illustrating the second metal pattern of FIG. 8.

FIG. 15 is an enlarged view illustrating an embodiment of part A of FIGS. 9, 10, 11, 12, 13, and 14.

FIG. 16 is a view illustrating another embodiment of part A of FIGS. 9, 10, 11, 12, 13, and 14.

FIG. 17 is a graph illustrating pixel position versus surface flatness according an embodiment of the disclosure and a comparative embodiment.

FIGS. 18, 19, 20, 21, 22, 23, and 24 are views illustrating a manufacturing method of the display device and the electronic device including the display device according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in greater detail with reference to the accompanying drawings. Same reference numerals will be used for the same components in the drawings, and any repetitive detailed descriptions of the same components will be omitted or simplified.

The display device according to an embodiment may be applied to a variety of electronic devices. The electronic device according to an embodiment includes the aforementioned display device and may include a module or apparatus having other additional functions in addition to the display device.

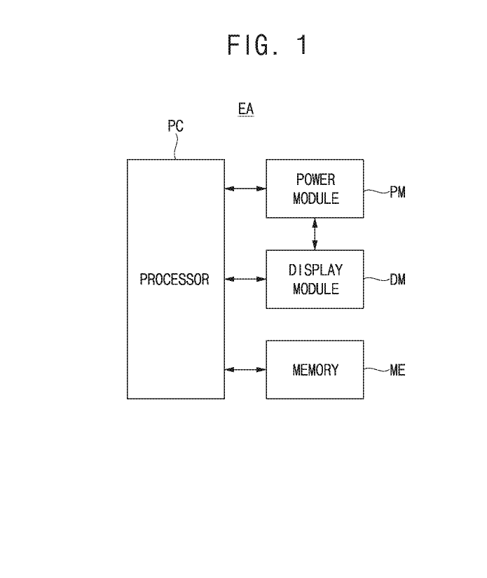

FIG. 1 is a block diagram illustrating an electronic device according to an embodiment.

Referring to FIG. 1, an electronic device EA according to an embodiment may include a display module DM, a processor PC, a memory ME, and a power module PM.

The processor PC may include a central processing unit (“CPU”), an application processor (“AP”), a graphic processing unit (“GPU”), a communication processor (“CP”), an image signal processor (“ISP”), and/or a controller.

Data information used for operation of the processor PC or the display module DM may be stored in the memory ME. When the processor PC executes an application stored in the memory ME, an image data signal and/or an input control signal is transmitted to the display module DM, and the display module DM may process received signal and output image information through a display screen.

The power module PM may include a power supply module such as a power adapter and/or a battery device, and a power conversion module that converts power supplied by the power supply module to generate power used for operation of the electronic device EA.

At least one of the components of the electronic device EA described above may be included in the display device according to the above-described embodiments. In addition, some of individual modules functionally included in one module may be included in the display device, and others may be provided separately from the display device. In an embodiment, for example, the display device may include the display module DM, and the processor PC, the memory ME, and the power module PM may be provided in the form of another device in the electronic device EA other than the display device. In an embodiment, the display device may operate based on the image data signal and the input control signal.

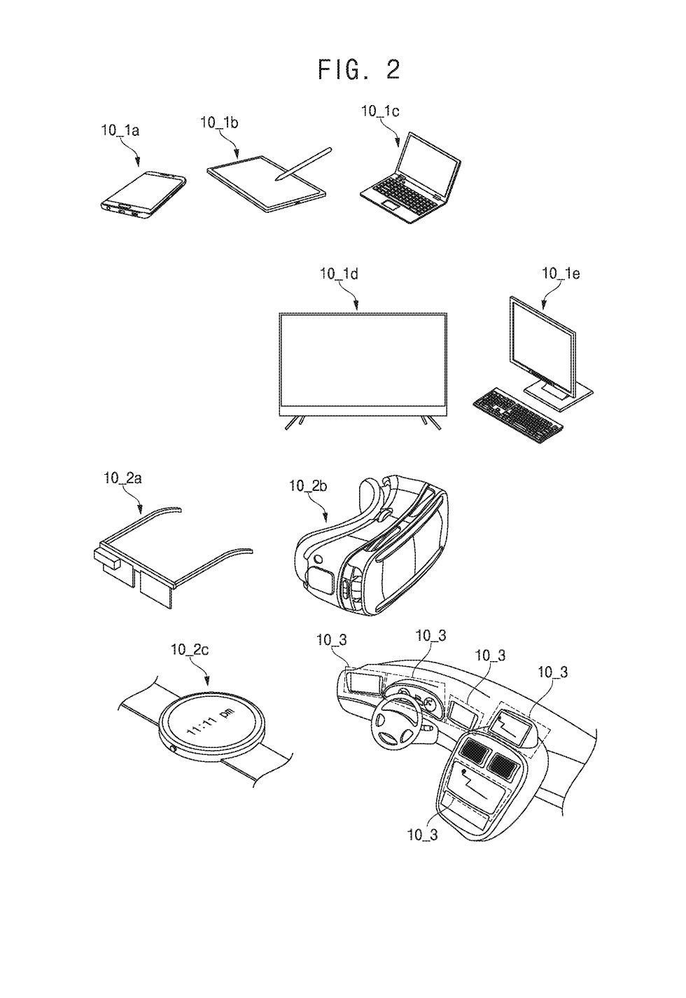

FIG. 2 is a schematic diagram of an electronic device according to various embodiments.

Referring to FIG. 2, one or more suitable electronic devices to which display devices according to an embodiment are applied may include not only electronic devices for image display such as a smartphone 10_1a, a tablet personal computer (PC) 10_1b, a laptop 10_1c, a television (TV) 10_1d, a desk monitor 10_1e, and/or the like, but wearable electronic devices including display modules such as a smart glass 10_2a, a head mounted display 10_2b, a smart watch 10_2c, and/or the like, vehicle electronic device 10_3 including display modules such as on a vehicle's instrument panel, a center fascia, a center information display (“CID”) located on a dashboard, a room mirror display, and/or the like.

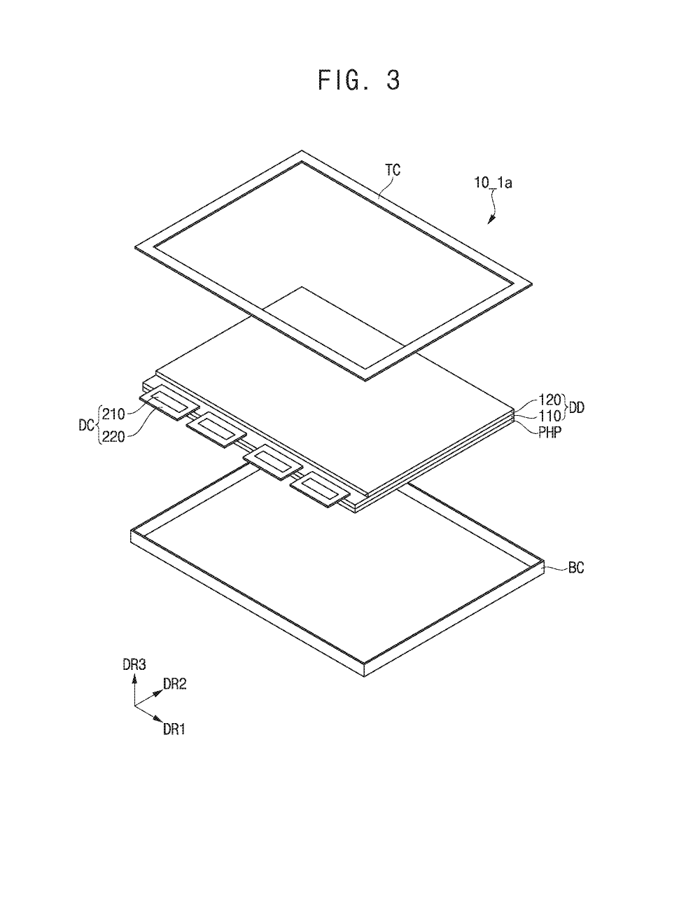

FIG. 3 is a view illustrating an electronic device according to an embodiment.

Referring to FIG. 3, an electronic device according to an embodiment (e.g., 10_1a) may include a display device DD, a heat dissipator PHP, and an outer case accommodating the display device DD and the heat dissipator PHP.

In FIG. 3, the first direction DR1, the second direction DR2, and the third direction DR3 may cross each other. For example, the first direction DR1, the second direction DR2, and the third direction DR3 may be perpendicular to each other.

For example, a plane may be defined by the first direction DR1 and the second direction DR2. For example, a normal direction of the plane (e.g., a direction of a thickness of the display device DD) may be the third direction DR3. The third direction DR3 may be a thickness direction of the electronic device.

Here, “top”, “tower”, and “upper surface” may mean a direction in which a second substrate 120 is disposed relative to a first substrate 110 of the display device DD, i.e., the third direction DR3. Here, “bottom”, “ground, base”, and “lower surface” may mean a direction in which the heat dissipator PHP is disposed relative to the first substrate 110 of the display DD, i.e., an opposite direction to the third direction DR3. Also, “left”, “right”, “up”, “down” may refer to the direction of the display device DD in a plan view. For example, “right” may mean the first direction DR1, “left” may mean the opposite direction to the first direction DR1, “up” may mean the second direction DR2, and “down” may mean the opposite direction to the second direction DR2.

In an embodiment, for example, the outer case may include an upper cover TC disposed on the upper part of the display device DD and a lower cover BC disposed on the lower part of the display device DD.

The upper cover TC may be positioned to cover an edge of the upper surface. The display device DD may include a display area in which a plurality of pixels is disposed. The display area may be surrounded by an peripheral area. In an embodiment, for example, the upper cover TC may cover the display area.

The lower cover BC may be positioned to cover an entire lower surface. The display device DD may be connected to a drive chip DC. In an embodiment, for example, the drive chip DC may include a drive circuit 210 and a flexible film 220. The flexible film 220 may be bent in a way such that the drive circuit 210 may be adjacent to a back surface of the display device DD. In an embodiment, for example, a surface on which a light emitted from the plurality of pixels is displayed as an image may be a front surface, and a surface facing in the third direction DR3 to the front may be a back surface. The front surface of the display device DD may be adjacent to the upper cover TC, and the back surface of the display device DD may be adjacent to the lower cover BC.

In the outer case, a seating groove may be defined. An object to be protected may be accommodated in a space defined by the seating groove. In an embodiment, for example, the object to be protected may be the display device DD. In another embodiment, for example, the object to be protected may be a variety of electronic devices including the display device DD. FIG. 3 shows an embodiment where the electronic device including the display device DD is the smartphone 10_1a as an example, however, the disclosure is not limited thereto. As described above, the electronic devices EA may be implemented in various forms.

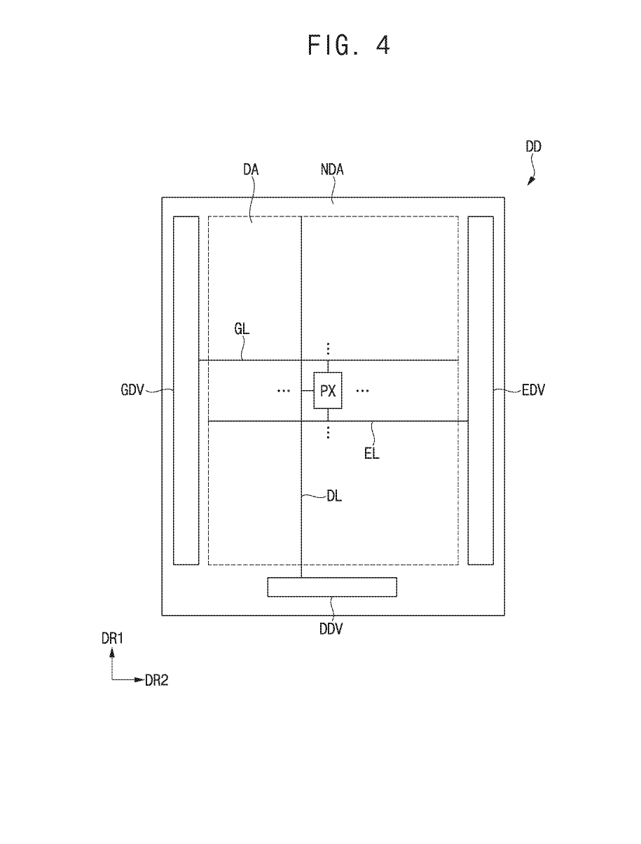

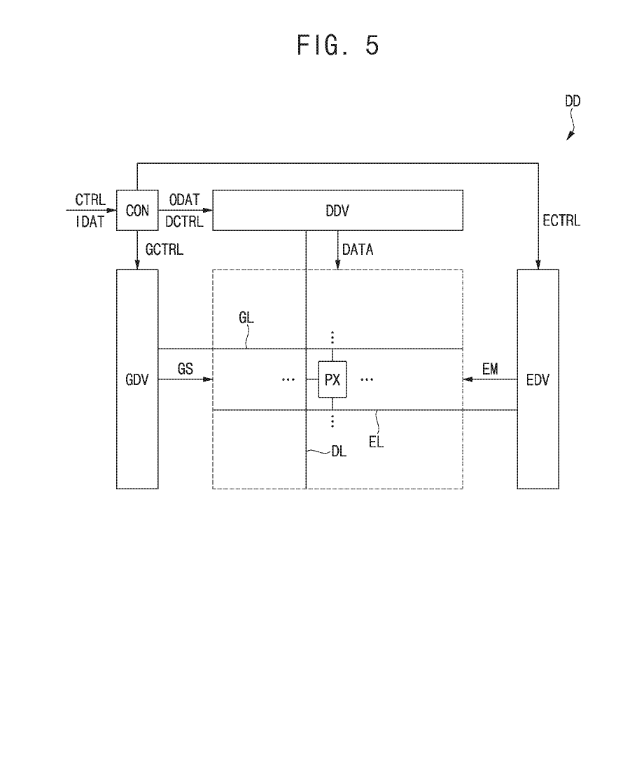

FIG. 4 is a plan view illustrating a display device of FIG. 3. FIG. 5 is a block diagram illustrating the display device of FIG. 3.

Referring to FIGS. 3, 4 and 5, an embodiment of the display device DD may include the display area DA and a non-display area NDA (i.e., the peripheral area).

The display area DA may be an area that displays the image. A plurality of pixels PX may be disposed in the display area DA. As the pixels PX emit light, the display area DA may display the image.

The non-display area NDA may be an area that does not display the image. The non-display area NDA may surround at least a portion of the display area DA. In an embodiment, for example, the non-display area NDA may entirely surround the display area DA. A driver that provides a signal or a voltage to the pixels PX may be disposed in the non-display area NDA. In an embodiment, for example, the driver may include a gate driver GDV, a light-emitting driver EDV, a data driver DDV, and a controller CON.

Each of the pixels PX may be electrically connected to the gate driver GDV, the light-emitting driver EDV, and the data driver DDV. In an embodiment, each of the pixels PX may be connected to the gate driver GDV through a gate line GL, may be connected to the light-emitting driver EDV through a light-emitting line EL, and may be connected to the data driver DDV through a data line DL. Accordingly, each of the pixels PX may receive a gate signal GS, a light-emitting signal EM, and a data voltage DATA.

The gate driver GDV may receive a gate control signal GCTRL from the controller CON. The gate driver GDV may generate the gate signal GS based on the gate control signal GCTRL. The gate signal GS may be provided to each of the pixels PX through the gate line GL.

The light-emitting driver EDV may receive a light-emitting control signal ECTRL from the controller CON. The light-emitting driver EDV may generate the light-emitting signal EM based on the light-emitting control signal ECTRL. The light-emitting signal EM may be provided to each of the pixels PX through the light-emitting line EL.

The data driver DDV may receive a data control signal DCTRL and output image data ODAT from the controller CON. The data driver DDV may generate the data voltage DATA based on the data control signal DCTRL and the output image data ODAT. The data voltage DATA may be provided to each of the pixels PX through the data line DL.

The controller CON may receive a control signal CTRL and input image data IDAT from an external device (e.g., GPU). The controller CON may generate the gate control signal GCTRL, the light-emitting control signal ECTRL, the data control signal DCTRL, and the output image data ODAT based on the control signal CTRL and the input image data IDAT. The controller CON may control the gate driver GDV, the light-emitting driver EDV, and the data driver DDV.

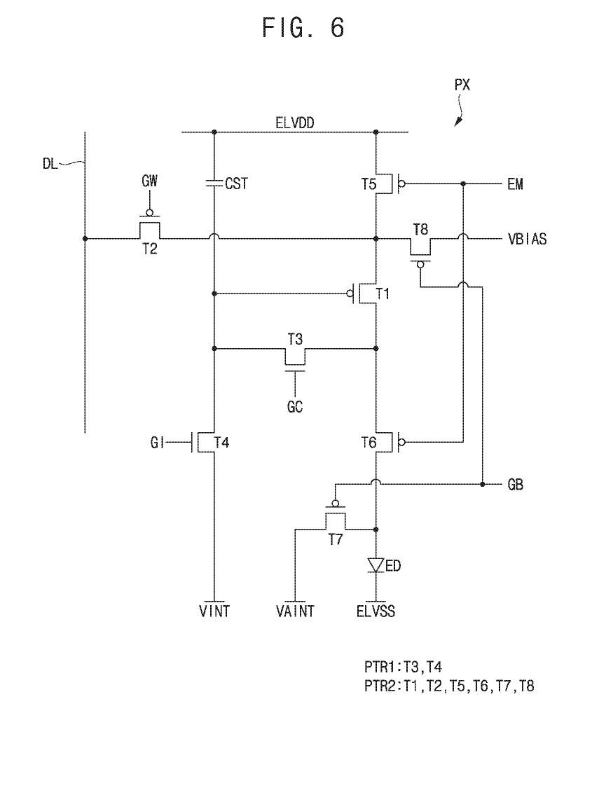

FIG. 6 is a circuit diagram illustrating a pixel of FIGS. 4 and 5.

Referring to FIGS. 4, 5, and 6, an embodiment of the pixel PX may include a first transistor T1, a second transistor T2, a third transistor T3, a fourth transistor T4, a fifth transistor T5, a sixth transistor T6, a seventh transistor T7, an eighth transistor T8, a storage capacitor CST, and a light-emitting element EE.

A first terminal of the first transistor T1 may be connected to the data line DL via the second transistor T2. In an embodiment, for example, the first transistor T1 may apply a data voltage from the data line DL through the first terminal and generate a driving current corresponding to the data voltage.

A second terminal of the first transistor T1 may be connected to the light-emitting element EE. In an embodiment, for example, the first transistor T1 may apply the driving current to the light-emitting element EE. A gate terminal of the first transistor T1 may be connected to the storage capacitor CST.

A first terminal of the second transistor T2 may be connected to the data line DL. A second terminal of the second transistor T2 may be connected to the first terminal of the first transistor T1. A gate write signal GW may be applied to a gate terminal of the second transistor T2.

Accordingly, the second transistor T2 may be turned on by the gate write signal GW. During an interval when the second transistor T2 is turned on (i.e., during a turn-on period of the second transistor T2), the second transistor T2 may apply the data voltage to the first transistor T1.

A first terminal of the third transistor T3 may be connected to the second terminal of the first transistor T1. A second terminal of the third transistor T3 may be connected to the gate terminal of the first transistor T1. The gate compensate signal GC may be applied to a gate terminal of the third transistor T3.

Accordingly, the third transistor T3 may be turned on by the gate compensate signal GC. During an interval when the third transistor T3 is turned on, the third transistor T3 may compensate a threshold voltage as the third transistor T3 element-connects the first transistor T1.

A first initialization voltage VINT may be applied to a first terminal of the fourth transistor T4. A second terminal of the fourth transistor T4 may be connected to the gate terminal of the first transistor T1. A first gate initialization signal GI may be applied to a gate terminal of the fourth transistor T4.

Accordingly, the fourth transistor T4 may turned on by the first gate initialization signal GI. During an interval when the fourth transistor T4 is turned on, the fourth transistor T4 may apply the first initialization voltage VINT to the gate terminal of the first transistor T1.

The first power voltage ELVDD may be applied to a first terminal of the fifth transistor T5. A second terminal of the fifth transistor T5 may be connected to the first terminal of the first transistor T1. A light emission control signal EM may be applied to a gate terminal of the fifth transistor T5.

Accordingly, the fifth transistor T5 may be turned on by the light emission control signal EM. During an interval when the fifth transistor T5 is turned on, the fifth transistor T5 may apply the first power voltage ELVDD to the first transistor T1.

In an embodiment, the first power voltage ELVDD and a second power voltage ELVSS applied to the light-emitting element EE may be constant voltages. The first power voltage ELVDD and the second power voltage ELVSS may have different voltage levels each other.

A first terminal of the sixth transistor T6 may be connected to the second terminal of the first transistor T1. A second terminal of the sixth transistor T6 may be connected to the light-emitting element EE. The light emission control signal EM may be applied to a gate terminal of the sixth transistor.

Accordingly, the sixth transistor T6 may be turned on by the light emission control signal EM. During an interval when the sixth transistor T6 is turned on, the sixth transistor T6 may apply the driving current to the light-emitting element EE.

A second initialization voltage VAINT may be applied to a first terminal of the seventh transistor T7. A second terminal of the seventh transistor T7 may be connected to the light-emitting element EE. A second gate initialization signal GB may be applied to a gate terminal of the seventh transistor T7.

Accordingly, the seventh transistor T7 may be turned on by the second gate initialization signal GB. During an interval when the seventh transistor T7 is turned on, the seventh transistor T7 may apply the second initialization voltage VAINT to the light-emitting element EE.

A bias voltage VBIAS may be applied to a first terminal of the eighth transistor T8. A second terminal of the eighth transistor T8 may be connected to the first terminal of the first transistor T1. The second gate initialization signal GB may be applied to the gate terminal of the eighth transistor T8.

Accordingly, the eighth transistor T8 may be turned on by the second gate initialization signal GB. During an interval when the eighth transistor T8 is turned on, the eighth transistor T8 may apply the bias voltage VBIAS to the first transistor T1.

A first terminal of the storage capacitor CST may be connected to the gate terminal of the first transistor T1. The first power voltage ELVDD may be applied to a second terminal of the storage capacitor CST, which is opposite to the first terminal.

The storage capacitor CST may be used to maintain a voltage level of a gate electrode which is the gate terminal of the first transistor T1 during an inactive interval of the gate write signal GW.

In an embodiment, for example, the first transistor T1, the second transistor T2, the fifth transistor T5, the sixth transistor T6, the seventh transistor T7, and the eighth transistor T8 may be a p-channel metal-oxide-semiconductor (“PMOS”) transistor, and the third transistor T3 and the fourth transistor T4 may be a n-channel metal-oxide-semiconductor (“NMOS”) transistor.

The NMOS transistor may use an electron as a main charge carrier. The NMOS transistor may be activated when a positive voltage is applied to the gate. The NMOS transistor may have a relatively high current density and a fast switching speed, so the NMOS transistor is generally used in high-speed, high-performance electronic devices.

On the other hand, the PMOS transistor may use a hole as the main charge carrier. The PMOS transistor may be activated when a negative voltage is applied to the gate. The PMOS transistor may have a relatively low switching speed but low power consumption, so the PMOS transistor may be used in portable electronic devices that require reduced power consumption.

However, embodiments shown in FIGS. 1 to 6 are merely examples, and the disclosure is not limited thereto. In another embodiment, for example, types of transistors of each of the first to eighth transistors (T1, T2, T3, T4, T5, T6. T7, T8) are not limited thereto.

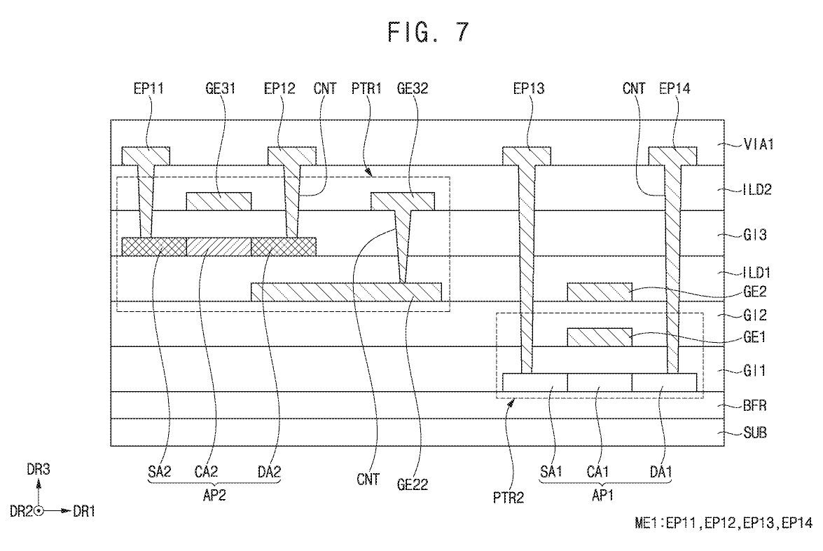

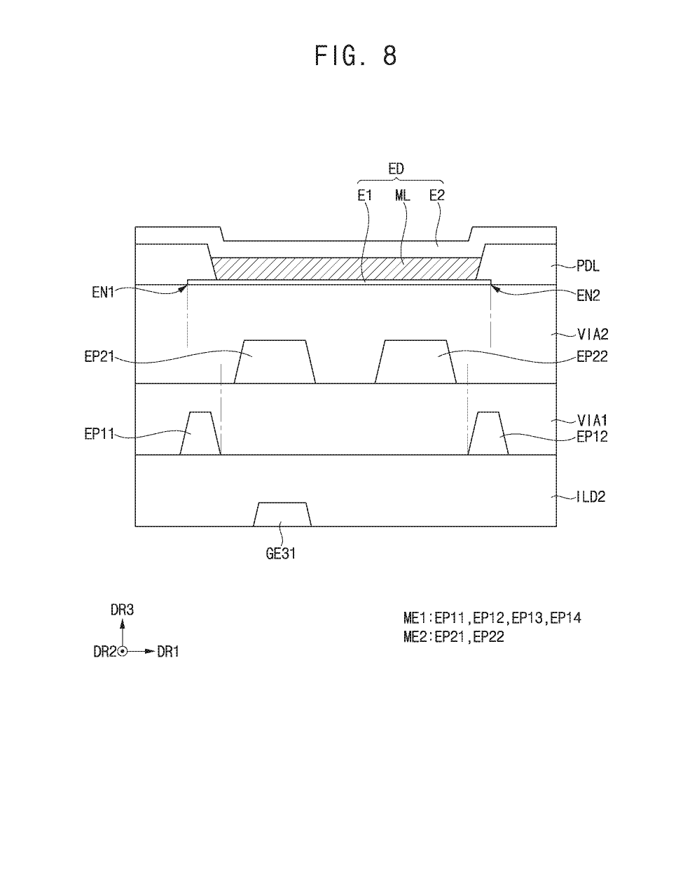

FIG. 7 is a cross-sectional view illustrating an example of transistors of FIG. 6. FIG. 8 is a cross-sectional view illustrating a second metal pattern included in the electronic device of FIG. 1.

For example, FIG. 8 is a cross-sectional view taken from an upper part of a second interlayer insulating layer ILD2 of FIG. 7. For convenience of illustration and description, in FIG. 8, elements below the second interlayer insulating layer ILD2, i.e., elements from a substrate SUB to a third gate insulating layer GI3 are omitted.

Referring to FIGS. 6, 7, and 8, an embodiment of the display device DD may include the substrate SUB, a buffer layer BFR, a first active pattern AP1, a first gate insulating layer GI1, a first gate electrode GE1, a second gate insulating layer GI2, a second gate electrode GE2, a second-second gate electrode GE22, a first interlayer insulating layer ILD1, a second active pattern AP2, the third gate insulating layer GI3, a first third gate electrode GE31, a second third gate electrode GE32, the second interlayer insulating layer ILD2, a first metal patterns ME1, and a first via insulating layer VIA. In an embodiment, for example, the first metal patterns may include or define a first source electrode EP13, a first drain electrode EP14, a second source electrode EP11, and a second drain electrode EP12.

The substrate SUB may include a transparent or opaque material. The substrate SUB may include glass, quartz, plastic, or the like. These may be used alone or in combination with each other.

The buffer layer BFR may be disposed on the substrate SUB. The buffer layer BFR may prevent metal atoms or impurities from being diffused from the substrate SUB to transistors. In addition, the buffer layer BFR may improve a flatness of a surface of the substrate SUB when the surface of the substrate SUB is not uniform. The buffer layer BFR may include an inorganic material such as silicon oxide (SiOₓ), silicon nitride (SiNₓ), silicon carbide (SiCₓ), silicon oxy nitride (SiOₓN_{y}), silicon oxy carbide (SiOₓC_{y}), or the like. These may be used alone or in combination with each other.

The first active pattern AP1 may be disposed on the buffer layer BFR. The first active pattern AP1 may include a source area SA1, a drain area DA1, and a channel area CA1 positioned between the source area SA1 and the drain area DA1. In an embodiment, the first active pattern AP1 may include a silicon semiconductor material. In an embodiment, for example, the first active pattern AP1 may include amorphous silicon, polycrystalline silicon, or the like. These may be used alone or in combination with each other.

In an embodiment, the first active pattern AP1 may include a P-type impurity. In an embodiment, for example, the P-type impurity may include boron (B) ions. The P-type impurity may be doped into the source area SA1 and the drain area DA1 of the first active pattern AP1. In an embodiment, for example, the first active pattern AP1 may correspond to the first terminals and the second terminals of the first, second, fifth, sixth, seventh, and eighth transistors T1, T2, T5, T6, T7, and T8.

The first gate insulating layer GI1 may be disposed on the buffer layer BFR, and may cover the first active pattern AP1. The first gate insulating layer GI1 may include an inorganic material such as silicon oxide, silicon nitride, silicon carbide, silicon oxy nitride, silicon oxy carbide, or the like. These may be used alone or in combination with each other.

The first gate electrode GE1 may be disposed on the first gate insulating layer GI1. The first gate electrode GE1 may overlap the channel area CA1 of the first active pattern AP1 in the third direction DR3 (or a thickness direction of the substrate SUB). The first gate electrode GE1 may include metal, alloy, conductive metal oxide, metal nitride, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. In an embodiment, for example, the conductive metal oxide may include indium tin oxide, indium zinc oxide, or the like. In an embodiment, for example, the metal nitride may include aluminum nitride (AlNₓ), tungsten nitride (WNₓ), chromium nitride (CrNₓ), or the like. These may be used alone or in combination with each other. In an embodiment, for example, the first gate electrode GE1 may correspond to the gate terminals of the first, second, fifth, sixth, seventh, and eighth transistors T1, T2, T5, T6, T7, and T8.

The second gate insulating layer GI2 may be disposed on the first gate insulating layer GI1, and may cover the first gate electrode GE1. In an embodiment, for example, the second gate insulating layer GI2 may include an inorganic material such as silicon oxide, silicon nitride, silicon carbide, silicon oxy nitride, silicon oxy carbide, or the like. These may be used alone or in combination with each other.

The second gate electrode GE2 and the second-second gate electrode GE22 may be disposed on the second gate insulating layer GI2. The second gate electrode GE2 and the second-second gate electrode GE22 may be disposed in (or directly on) a same layer as each other. In an embodiment, for example, the second gate electrode GE2 and the second-second gate electrode GE22 may include or be formed of a same material.

The second gate electrode GE2 and the second-second gate electrode GE22 may include metal, alloy, conductive metal oxide, metal nitride, or the like. These may be used alone or in combination with each other.

The second gate electrode GE2 may overlap the first gate electrode GE1 in the third direction DR3. In an embodiment, for example, the first gate electrode GE1 and the second gate electrode GE2 may correspond to the storage capacitor CST of FIG. 6.

In an embodiment, for example, the second-second gate electrode GE22 may correspond to lower gate terminals of third transistor T3 and the fourth transistor T4 of FIG. 6.

The first interlayer insulating layer ILD1 may be disposed on the second gate insulating layer GI2, and may cover the second gate electrode GE2. In an embodiment, for example, the first interlayer insulating layer ILD1 may include silicon oxide, silicon nitride, silicon carbide, silicon oxy nitride, silicon oxy carbide, or the like. These may be used alone or in combination with each other.

The second active pattern AP2 may be disposed on the first interlayer insulating layer ILD1. The second active pattern AP2 may include a material different from a material of the first active pattern AP1. In an embodiment the second active pattern AP2 may include an oxide semiconductor material. In an embodiment, for example, the second active pattern AP2 may include indium gallium zinc oxide, indium tin zinc oxide, or the like. These may be used alone or in combination with each other.

The second active pattern AP2 may include a source area SA2, a drain area DA2, and a channel area CA2 positioned between the source area SA2 and the drain area DA2. In an embodiment, the second active pattern AP2 may include an N-type impurity. In an embodiment, for example, the N-type impurity may include phosphorus (P) ions. The N-type impurity may be doped into the source area SA2 and the drain area DA2 of the second active pattern AP2. In an embodiment, for example, the second active pattern AP2 may correspond to the first terminals and the second terminals of the third and fourth transistors T3 and T4 of FIG. 6.

The third gate insulating layer GI3 may be disposed on the first interlayer insulating layer ILD1, and may cover the second active pattern AP2. The third gate insulating layer GI3 may include an inorganic material such as silicon oxide, silicon nitride, silicon carbide, silicon oxy nitride, silicon oxy carbide, or the like. These may be used alone or in combination with each other.

The first third gate electrode GE31 and the second third gate electrode GE32 may be disposed on the third gate insulating layer GI3. The first third gate electrode GE31 and the second third gate electrode GE32 may be disposed in (or directly on) a same layer as each other. In an embodiment, for example, the first third gate electrode GE31 and the second third gate electrode GE32 may be formed by a same process using a same material.

The first third gate electrode GE31 and the second third gate electrode GE32 may include metal, alloy, conductive metal oxide, metal nitride, or the like. These may be used alone or in combination with each other.

The first third electrode GE31 may overlap the channel area CA2 of the second active pattern AP2 in the third direction DR3. In an embodiment, for example, the first third electrode GE31 may correspond to the upper gate terminals of the third and fourth transistors T3 and T4 of FIG. 6.

The second third electrode GE32 may be electrically connected to the second-second gate electrode GE22 through a contact hole CNT penetrating (i.e., defined or formed through) the third gate insulating layer GI3 and interlayer insulating layer IL1. In an embodiment, for example, the second third electrode GE32 may correspond to the upper gate terminals of third transistor T3 and the fourth transistor T4 of FIG. 6.

The second interlayer insulating layer ILD2 may be disposed on the third gate insulating layer GI3, and may cover the first third gate electrode GE31 and the second third electrode GE32. In an embodiment, for example, the second interlayer insulating layer ILD2 may include silicon oxide, silicon nitride, silicon carbide, silicon oxy nitride, silicon oxy carbide, or the like. These may be used alone or in combination with each other.

First metal patterns (e.g., the first source electrode EP13, the first drain electrode EP14, the second source electrode EP11, and the second drain electrode EP12) may be disposed on the second interlayer insulating layer ILD2. The first source electrode EP13, the first drain electrode EP14, the second source electrode EP11, and the second drain electrode EP12 may be formed by a same process using a same material.

The first source electrode EP13, the first drain electrode EP14, the second source electrode EP11, and the second drain electrode EP12 may include metal, alloy, conductive metal oxide, metal nitride, or the like. These may be used alone or in combination with each other.

The first source electrode EP13 may be in contact with the source area SA1 of the first active pattern AP1 through a contact hole penetrating (defined through) portions of the first, second, and third gate insulating layers GI1, GI2, and GI3 and the first and second interlayer insulating layers ILD1 and ILD2.

The first drain electrode EP14 may be in contact with the drain area DA1 of the first active pattern AP1 through a contact hole penetrating (defined through) portions of the first, second, and third gate insulating layers GI1, GI2, and GI3 and the first and second interlayer insulating layers ILD1 and ILD2.

The second source electrode EP11 may be in contact with the source area SA2 of the second active pattern AP2 through a contact hole (e.g., CNT) penetrating (defined through) portions of the third gate insulating layer GI3 and the second interlayer insulating layer ILD2.

The second drain electrode EP12 may be in contact with the drain area DA2 of the second active pattern AP2 through a contact hole penetrating (defined through) portions of the third gate insulating layer GI3 and the second interlayer insulating layer ILD2.

Accordingly, a second type transistor PTR2 including the first active pattern AP1, the first gate electrode GE1, and some of the first metal patterns ME1 (e.g., the first source electrode EP13 and the first drain electrode EP14) may be disposed on the substrate SUB.

In addition, a first type transistor PTR1 including the second-second gate electrode GE22, the second active pattern AP2, the first third gate electrode GE31, the second third gate electrode GE32, and some of the first metal patterns ME1 (e.g., the second source electrode EP11 and the second drain electrode EP12) may be disposed on the substrate SUB. In other words, in an embodiment, the second type transistor PTR2 may be disposed between the substrate SUB and the first type transistor PTR1.

The first via insulating layer VIA1 may be disposed on the second interlayer insulating layer ILD2, and may cover the first source electrode EP13, the first drain electrode EP14, the second source electrodeEP11, and the second drain electrode EP12. The first via insulating layer VIA1 may include an organic material. In an embodiment, for example, the first via insulating layer VIA1 may include phenol resin, acrylic resin, polyimide resin, polyamide resin, siloxane resin, epoxy resin, or the like. These may be used alone or in combination with each other.

In an embodiment, for example, the light-emitting element ED may overlap the first type transistor PTR1 and the second type transistor PTR2 of FIG. 7 in the third direction DR3. In FIG. 8, for convenience of illustration and description, the first type transistor PTR1 may be depicted mainly.

The second via insulating layer VIA2 may be disposed on the first via insulating layer VIA1. The second via insulating layer VIA2 may cover a second metal pattern ME2. In an embodiment, the second via insulating layer VIA2 may include an organic material. In an embodiment, for example, the second via insulating layer VIA2 may include a polyimide resin, a polyamide resin, a siloxane resin, an epoxy resin, or the like. These may be used alone or in combination with each other.

In an embodiment, the light-emitting element ED may be disposed on the first metal patterns ME1. The light-emitting element ED may include a first electrode E1, an intermediate layer ML, and a second electrode E2.

The first electrode E1 may be disposed on the second via insulating layer VIA2. The first electrode E1 may be connected to the second drain electrode EP14 through a contact hole penetrating (defined through) the second via insulating layer VIA2. The first electrode E1 may include a metal, an alloy, a conductive metal oxide, a conductive metal nitride, a transparent conductive material, or the like. These may be used alone or in combination with each other. In an embodiment, for example, the first electrode E1 may include silver (Ag) and indium tin oxide (“ITO”).

The pixel defining layer PDL may be disposed on the second via insulating layer VIA2. In an embodiment, the pixel defining layer PDL may partially cover the first electrode E1. In an embodiment, for example, the pixel defining layer PDL may cover a first end EN1 and a second end EN2 of the first electrode E1.

In an embodiment, a pixel opening may be defined in the pixel defining layer PDL to expose at least a portion of the first electrode E1. In an embodiment, for example, the pixel opening in the pixel defining layer PDL may expose a central portion of the first electrode E1, and the pixel defining layer PDL may cover both opposing ends of the first electrode E1 (e.g., the first end EN1 and the second end EN2).

The pixel defining layer PDL may include an inorganic material or an organic material. In an embodiment, for example, the pixel defining layer PDL may include an epoxy resin, a siloxane resin, or the like. These may be used alone or in combination with each other. However, the disclosure is not limited thereto. In an embodiment, for example, the pixel defining layer PDL may further include a light-blocking material including a black pigment, a black dye, or the like.

The intermediate layer ML may be disposed on the pixel defining layer PDL. The intermediate layer ML may be disposed on the first electrode E1 exposed by the pixel opening of the pixel defining layer PDL. The intermediate layer ML may include an organic light-emitting material. In an embodiment, for example, the intermediate layer ML may include a low-molecular organic compound or a high-molecular organic compound. However, the disclosure is not limited thereto. In an embodiment, for example, the intermediate layer ML may include a material such as a quantum dot.

The second electrode E2 may be disposed on the intermediate layer ML. The second electrode E2 may include a metal, an alloy, a conductive metal oxide, a conductive metal nitride, a transparent conductive material, or the like. In an embodiment, for example, the second electrode E2 may include aluminum (Al), platinum (Pt), silver (Ag), magnesium (Mg), gold (Au), chromium (Cr), tungsten (W), titanium (Ti), or the like. These may be used alone or in combination each other.

In an embodiment, the second metal pattern ME2 may be disposed between the first metal patterns ME1 and the first electrode E1. In an embodiment, for example, the second metal pattern ME2 may be disposed on the first via insulating layer VIA1. In an embodiment, for example, the second metal pattern ME2 may include a connecting electrode and a shielding pattern.

For example, the connecting electrode may be connected to the first drain electrode EP14 through a contact hole penetrating (defined through) the first via insulating layer VIA1. Accordingly, the connecting electrode may electrically connect the second type transistor PTR2 and the light-emitting element ED. In an embodiment, for example, the connecting electrode may include a metal, an alloy, a metal nitride, a conductive metal oxide, a transparent conductive material, or the like. These may be used alone or in combination with each other.

In an embodiment, the shielding pattern (e.g., EP21 of FIG. 8) may cover the first third gate electrode GE31. In a case of the NMOS transistor, there is an issue that an element moves due to external light. In an embodiment, for example, when light of a specific wavelength is incident on the NMOS transistor, the element characteristics in the channel may change due to the movement of electrons. This may change a performance of the NMOS transistor, resulting in a luminance difference that is different from a design. In an embodiment, the shielding pattern may be disposed on a light-emitting portion (e.g., a portion overlapping the pixel opening defined by the pixel defining layer PDL described below) to effectively prevent the change of the element characteristics by light incident thereon. The shielding pattern may shield the NMOS transistor located underneath from the external light.

In an embodiment, the slit may be defined in the second metal pattern ME2 at a position overlapping the pixel opening in the third direction DR3. In an embodiment, for example, as shown in FIG. 8, in a cross-sectional view, the second metal pattern ME2 may include a first portion EP21 and a second portion EP22 between which the slit is defined (the cross-section may be defined by the first direction DR1 and the third direction DR3).

In a case of a display device and an electronic device according to a comparative embodiment, the shielding pattern may be formed by being deposited over a large area. For example, the second metal pattern ME2 of FIG. 8 is shown to include a first part EP21 and a second part EP22, but in the case of the display device and the electronic device including the display device according to the comparative embodiment, the first part EP21 and the second part EP22 may have an extended form.

The deposition may be carried out using a sputtering facility. Due to a limitation of the facility, a top surface of the shielding pattern may be uneven. After being deposited over the large area, ends of the shielding pattern may be tapered.

If the pixel opening is formed on the tapered end of the shielding pattern, a flattening difference of the emitting part may occur. Depending on a size of a taper angle, overlay distortion by position may occur. Accordingly, characteristics of the viewing angle may deteriorate.

In order to effectively prevent the deterioration of the characteristics of the viewing angle due to the flattening difference of the emitting part, the display device and the electronic device including the display device according to the comparative embodiment may include a relatively thick insulating layer (e.g., the second via insulating layer VIA2). For example, a thickness of the second via insulating layer VIA2 may be relatively thick compared to other insulating layers. For another example, an additional insulating layer may be formed on the second via insulating layer VIA2. As described above, the insulating layer including the organic material (e.g., the second insulating layer VIA2) may have a flat top surface. Accordingly, in this case, the effects due to the taper may be minimized.

However, as the thickness of the insulating layer including the organic material increases, the manufacturing cost, time, or the like may increase. In addition, the thickness of the display device and the electronic device including the display device may also be thickened. In addition, the relatively thick insulating layer may cause new issues such as pixel shrinkage.

On the other hand, when the user looks at the display screen, the user may look at the display screen from the front with various viewing angles, e.g., from the lower part of the display screen to the upper part of the display screen, or from the side to the center of the display screen. For example, in the drive chip DC part of FIGS. 3 and 4, the display screen may be viewed in the second direction DR2, or the display screen may be tilted in the opposite direction of the first direction DR1 or the first direction DR1.

In this regard, wide angle distortion (“WAD”) characteristic is becoming important. The WAD characteristic refers to a characteristic that a color and brightness change depending on the viewing angle. For example, as the viewing angle becomes wider, the color and brightness may change inconsistently (i.e., color asymmetry).

In the case of the display device and the electronic device including the display device according to the comparative embodiment, the shielding pattern may not be flat up and down (e.g., in the opposite direction of the first direction DR1 or first direction DR1) or left and right (e.g., in the opposite direction of the second direction DR2 or the second direction DR2) as deposited over the large area (the flattening difference occurs). In this case, the color asymmetry may occur.

In the display device and the electronic device including the display device according to an embodiment of the disclosure, the slit may be defined in the second metal pattern ME2. By means of the slit, the second metal pattern ME2 may be formed to be small in size and at the same time symmetrical. Accordingly, the display device and the electronic device including the display device with slimming (no need to increase the thickness of the insulating layer) and the display quality (the viewing angle characteristic) with improved may be provided.

In an embodiment, in the cross-sectional view, the second metal pattern ME2 may be separated from the first end EN1 and the second end EN2 of the first electrode E1. In an embodiment, for example, the second metal pattern ME2 may not overlap both of the first end EN1 and the second end EN2 of the first electrode E1 in the third direction DR3.

If the second metal pattern ME2 overlaps the end (e.g., the first end EN1 and/or the second end EN2) of the first electrode E1 in the third direction DR3, the first electrode E1 may be bent due to the taper of the second metal pattern ME2. For example, if the second metal pattern ME2 overlaps only the first end EN1 in the third direction DR3, the first end EN1 may be located at a greater level than the second end EN2. In this case, color coordinate differences may cause the display quality degradation (e.g., unintended coloring).

However, in the display device (and the electronic device including the display device) according to an embodiment of the disclosure, the second metal pattern ME2 may not overlap the ends (e.g., the first end EN1 and the second end EN2) of the first electrode E1 in the third direction DR3. Accordingly, it is possible to effectively prevent the deterioration of the display quality due to the difference in the color coordinates.

In an embodiment, in the cross-sectional view, the second metal pattern ME2 may be spaced apart from the first metal patterns ME1. In an embodiment, for example, the second metal pattern ME2 may not overlap the first metal patterns ME1 in the third direction DR3.

When the second metal pattern ME2 overlaps the first metal patterns ME1 in the third direction DR3, the first electrode E1 may be bent due to the taper of the first metal patterns ME1. In an embodiment, for example, the first electrode E1 may be formed at a higher level by the combined height of the first metal patterns ME1 and the second metal pattern ME2 in an area where both the first metal pattern ME1 and the second metal pattern ME2 are formed than an area where the first metal pattern ME1 and the second metal pattern ME2 are not present. In this case, the color coordinate difference may degrade the display quality (e.g., to display with an unintended color).

However, in the display device (and the electronic device including the display device) according to an embodiment of the disclosure, the second metal pattern ME2 may not overlap the first metal patterns ME1 in the third direction DR3. In such an embodiment, as the bending formation of the first electrode E1 due to the taper of the first metal patterns ME1 is effectively prevented, the deterioration of display quality caused by the color coordinate difference may also be effectively prevented.

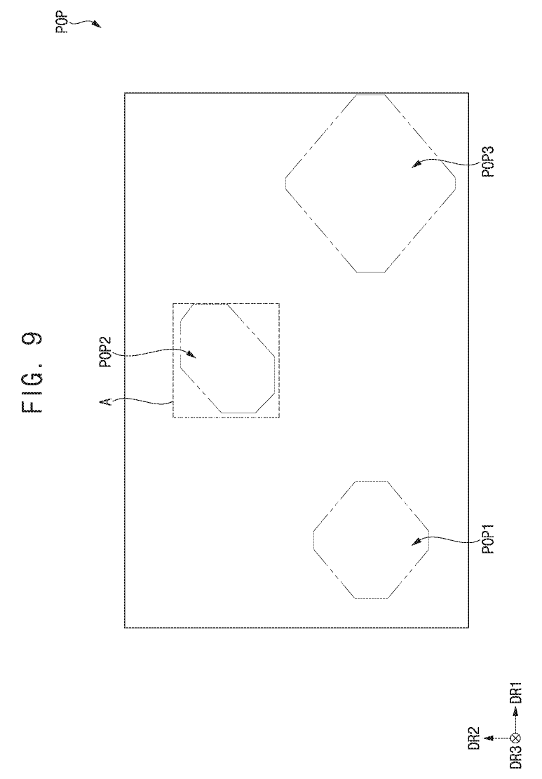

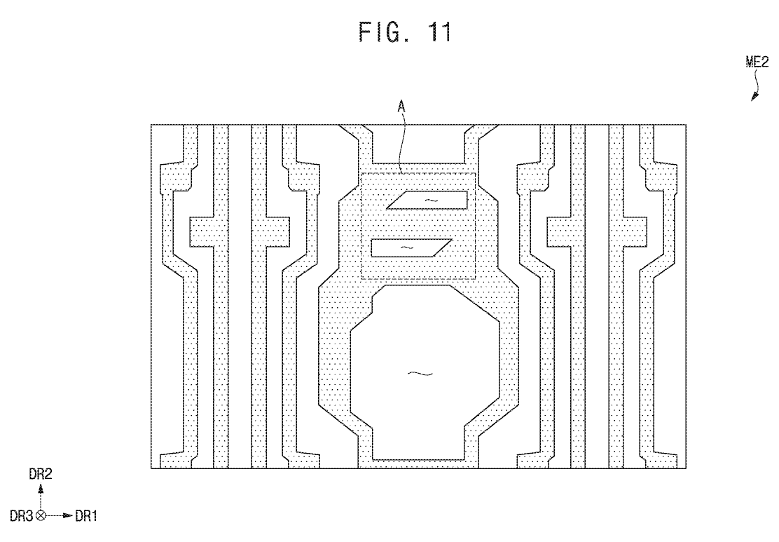

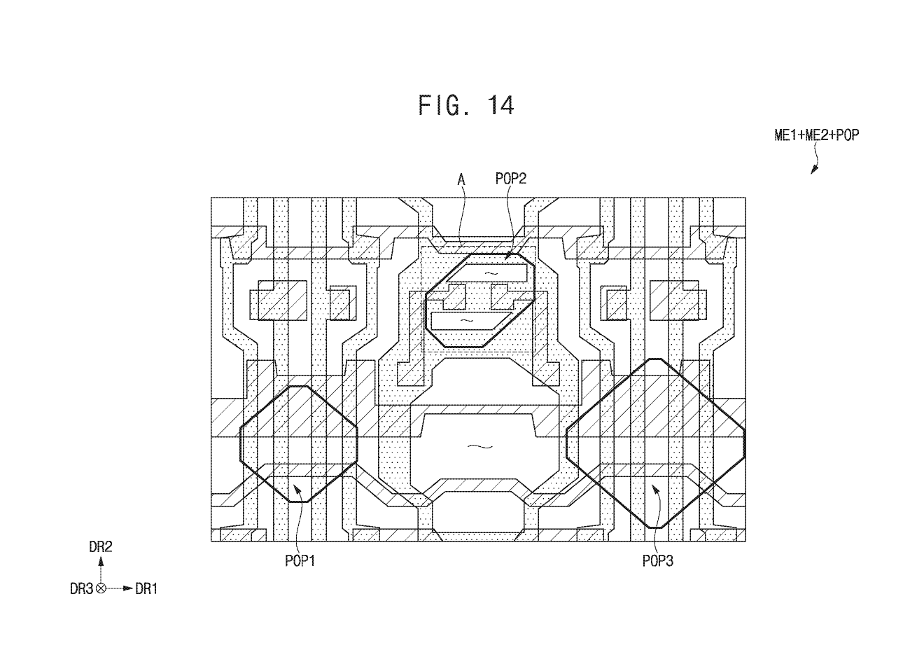

FIGS. 9, 10, 11, 12, 13, and 14 are plan views illustrating the second metal pattern of FIG. 8.

For example, FIGS. 9, 10, 11, 12, 13, and 14 mainly illustrate areas that include pixel openings POP through which first to third color lights are emitted.

Referring to FIG. 9, in an embodiment, the pixel openings POP may include a first opening POP1 of the pixel that emits a first color light, a second opening POP2 of the pixel that emits a second color light different from the first color light, and a third opening POP3 of the pixel that emits a third color light different from the first color light and the second color light.

In an embodiment, the first color light may be red light, the second color light may be green light, and the third color light may be blue light. However, the disclosure is not limited thereto. In an embodiment, for example, the first to third color light may be light-emitting colors other than the red, green, and blue colors. In another embodiment, for example, the first to third color light may emit a same color light as each other.

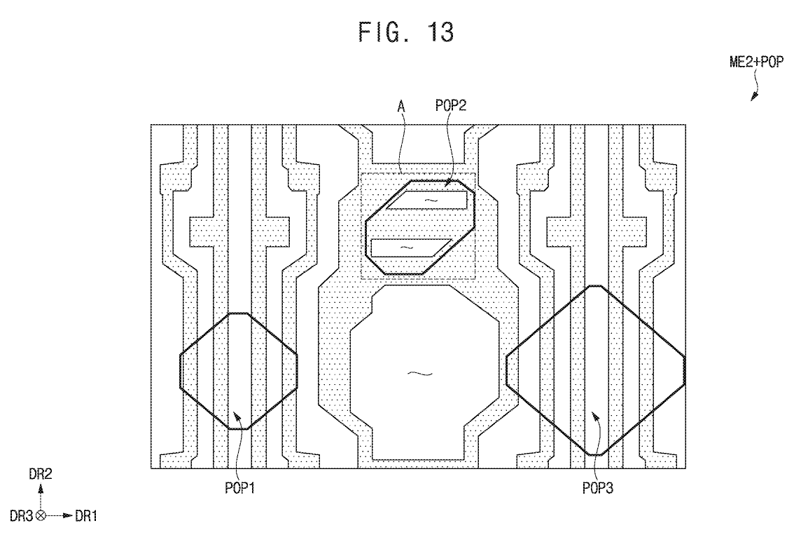

Referring to FIGS. 8, 9, 10, 11, 12, 13, and 14, in an embodiment, the second metal pattern ME2 may be disposed on the first metal pattern ME1. Here, as shown in part A, the slit may be defined at the position overlapping the pixel openings POP in a plan view (or when viewed in the third direction DR3). However, the disclosure is not limited thereto. In an embodiment, for example, the slit may also be defined at a location that does not overlap the pixel openings POP (refer to the lower part of the part A of FIG. 13) to minimize the effect due to the taper of the second metal pattern ME2. Accordingly, the second metal pattern ME2 may be minimized.

As shown in FIG. 13, in an embodiment, the slit may be defined to overlap at least a portion of the second opening POP2. In an embodiment, for example, where RGB pixels (the pixels that emits red light, the green light, and the blue light) are included, the viewing angle characteristic may be most sensitive to the pixels that emits the green light. Accordingly, the slit may be defined to overlap at least a portion of the second opening POP2. However, the disclosure is not limited thereto. In another embodiment, for example, the slit may be formed to overlap the first opening POP1 and the third opening POP3 such that the second metal pattern ME2 may have further reduced area.

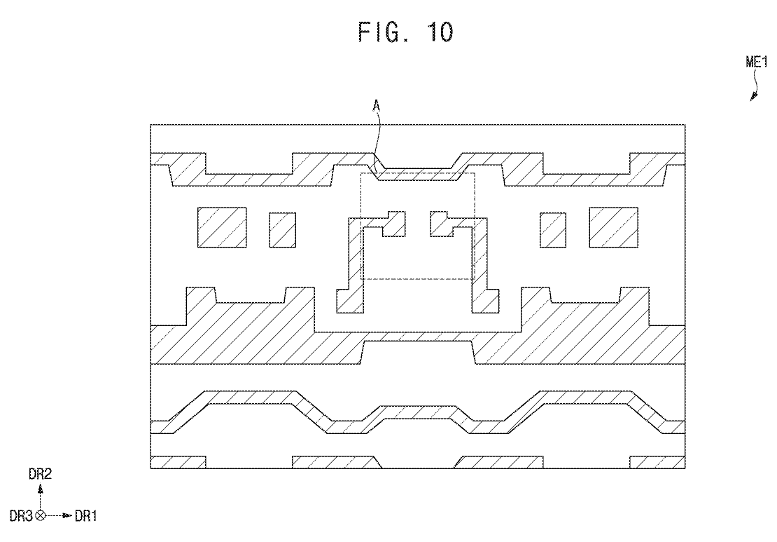

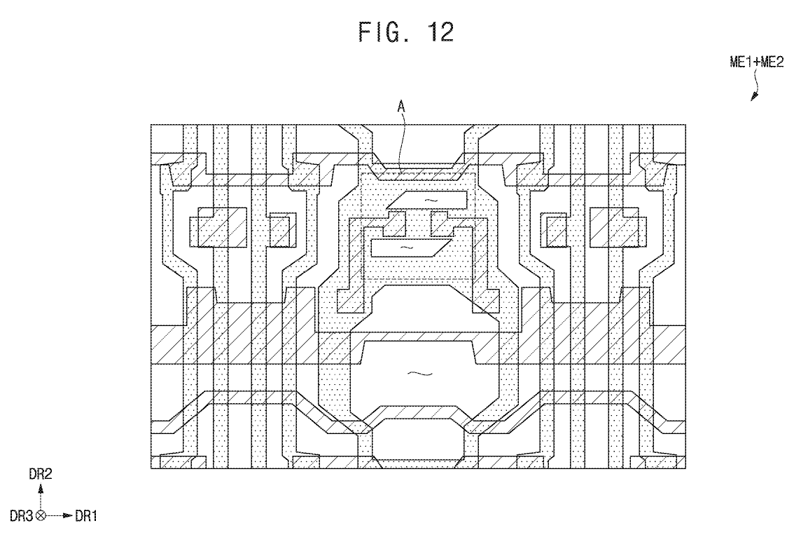

For example, in the part A of FIG. 10, in the symmetrical portion, the NMOS transistor may be located. As shown in FIG. 12, the slit may be defined in the second metal pattern ME2. The slit might not overlap the NMOS transistor. In other words, the NMOS transistor may be shielded by the second metal pattern ME2. Accordingly, the display device and the electronic device including the display area may be slimmed down to effectively prevent changes in the element properties by the outer light, and the color symmetry may be improved.

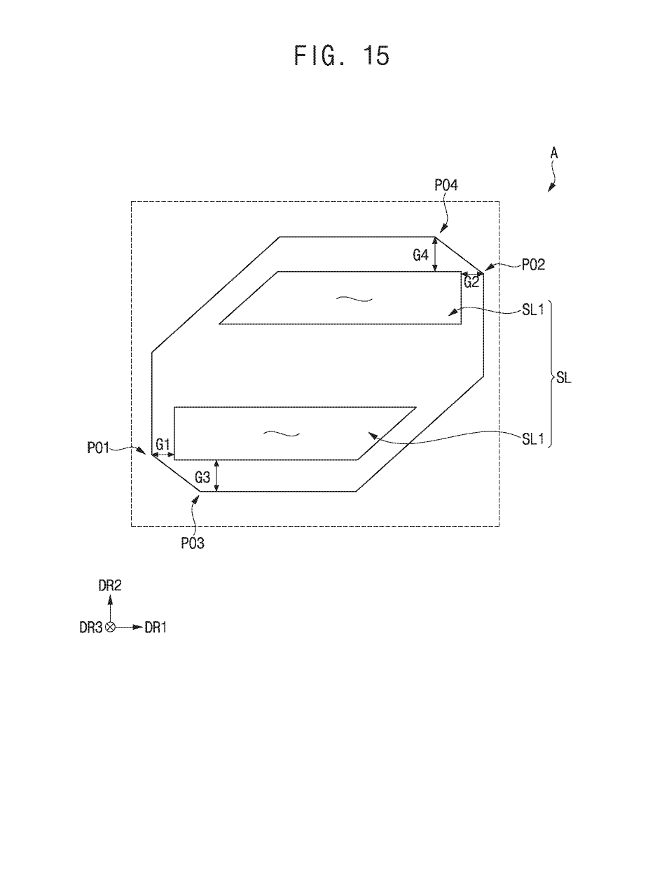

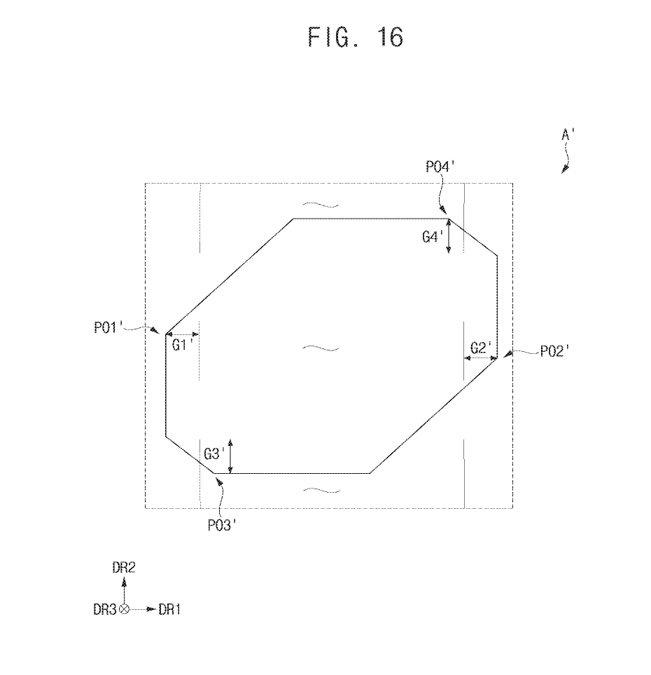

FIG. 15 is an enlarged view illustrating an embodiment of part A of FIGS. 9, 10, 11, 12, 13, and 14. FIG. 16 is a view illustrating another embodiment of part A of FIGS. 9, 10, 11, 12, 13, and 14.

Referring to FIGS. 8, 9, 10, 11, 12, 13, 14, and 15, in an embodiment, in the plan view, the slit SL of the second metal pattern ME2 defined at the position overlapping the pixel opening POP may be plural. In an embodiment, for example, a first slit SL1 and a second slit SL2 may be defined at the position overlapping the first opening POP1. As the number of the slit SL increases in the second metal pattern ME2, the second metal pattern ME2 may be more area reduction and the color symmetry may be further improved.

In an embodiment, the pixel opening (e.g., the first opening POP1) may include the first point PO1, the second point PO2, the third point PO3, and the fourth point PO4. The second point PO2 may be the position farthest from the first point PO1 to the first direction DR1. The third point PO3 may be the position that crosses the first point PO1. The fourth point PO4 may the position farthest from the third point PO3 to the second direction DR2.

In an embodiment, a first gap G1 and a second gap G2 may be the same as (or equal to) each other. The first gap G1 may be defined as a minimum distance between the first point PO1 of the pixel opening (e.g., the first opening POP1) and a nearest boundary line from the first point PO1 in the slit SL (e.g., a first side of the second slit SL2) in the first direction DR1. The second gap G2 may be defined as a minimum distance between the second point PO2 and a nearest boundary line from the second point PO2 in the slit SL (e.g., a second side of the first slit SL1) in the first direction DR1.

In such an embodiment, a third gap G3 and a fourth gap G4 may be the same as (or equal to) each other. The third gap G3 may be defined as a minimum distance between the third point PO3 of the pixel opening (e.g., the first opening POP1) and a nearest boundary line from the third point PO3 in the slit SL (e.g., a third side crossing the first side of the second slit SL2) in the second direction DR2. The fourth gap G4 may be defined as a minimum distance between the fourth point PO4 and a nearest boundary line from the fourth point PO4 in the slit SL (e.g., a fourth side crossing the second side of the first slit SL1) in the first direction DR1.

Referring to FIG. 16, in an embodiment, in the plan view, the slit SL of the second metal pattern ME2 defined at the position overlapping the pixel opening may be plural. In an embodiment, for example, in FIG. 15, the slit SL (e.g., the first slit SL1 and the second slit SL2) may be formed in parallel with the boundary of the pixel opening. In such an embodiment, as shown in FIG. 16, the formation of multiple slits differs in that the boundary of the pixel opening is not considered.

In an embodiment, as shown in FIG. 15, the boundary of the pixel opening and the second metal pattern ME2 overlap each other. In another embodiment, as shown in FIG. 16, a portion of the boundary of the pixel opening and the second metal pattern ME2 does not overlap each other. In other words, depending on where the slit SL is defined, the boundary of the pixel opening may overlap the second metal pattern ME2, as shown in FIG. 15, or a part where the boundary of the pixel opening and the second metal pattern ME2 do not overlap may be included, as shown in FIG. 16.

In an embodiment, the pixel opening (e.g., the first opening POP1) may include a first point PO1’, a second point PO2’, a third point PO3’, and a fourth point PO4’. The second point PO2’ may be the position farthest from the first point PO1’ in the first direction DR1. The third point PO3’ may be the position that crosses the first point PO1’. The fourth point PO4’ may be the position farthest from the third point PO3’ in the second direction DR2.

In an embodiment, as shown in FIG. 16, a first gap G1’ and a second gap G2’ may be the same as (or equal to) each other. The first gap G1’ may be defined as a minimum distance between the first point PO1’ of the pixel opening (e.g., the first opening POP1’) and a nearest boundary line from the first point PO1’ in the slit in the first direction DR1. The second gap G2’ may be defined as a minimum distance between the second point PO2’ and a nearest boundary line from the second point PO2’ in the slit in the first direction DR1.

In such an embodiment, a third gap G3’ and a fourth gap G4’ may be the same as (or equal to) each other. The third gap G3’ may be defined as a minimum distance between the third point PO3 of the pixel opening (e.g., the first opening POP1’) and a nearest boundary line from the third point PO3’ in the slit in the second direction DR2. The fourth gap G4’ may be defined as a minimum distance between the fourth point PO4’ and a nearest boundary line from the fourth point PO4’ in the slit in the first direction DR1.

The second metal pattern ME2 with the slit defined therein may be observed under a microscope at the position overlapping the pixel opening. As the slit of the second metal pattern ME2 has the symmetrical structure, the effect due to the taper may be minimized. Accordingly, the viewing angle characteristic (the color asymmetry) may be further improved.

In an embodiment, the first gap G1 (or the second gap G2) and the third gap G3 (or the fourth gap G4) may be identical to each other, or may differ from each other. Here, as a length of the gap (e.g., the first to fourth gaps (G1, G2, G3, G4)) increases, the taper angle may be reduced to further improve the viewing angle characteristic (the color asymmetry).

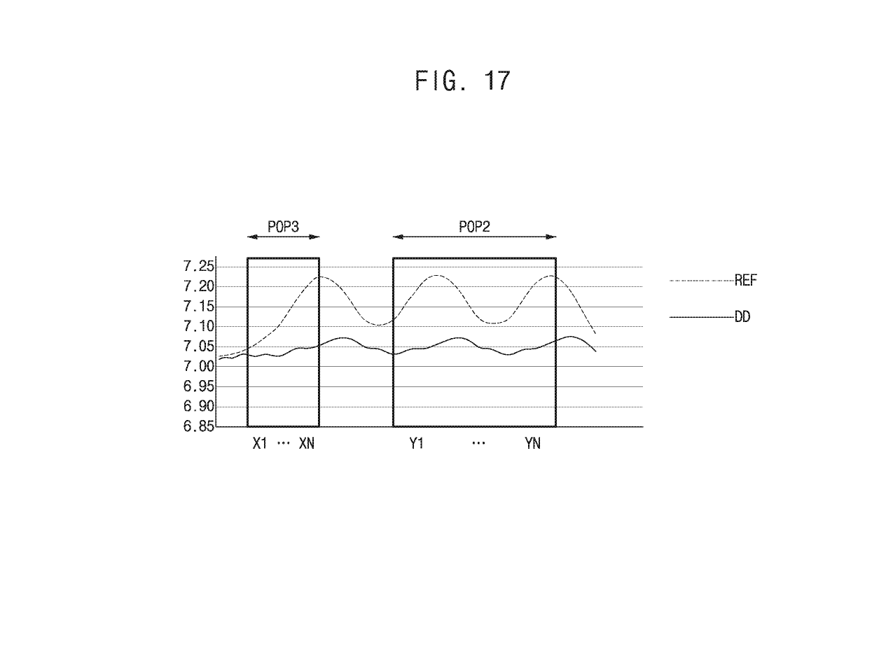

FIG. 17 is a graph illustrating pixel position versus surface flatness according an embodiment of the disclosure and a comparative embodiment.

In FIG. 17, the X-axis represents pixel position, and the Y-axis represents surface flatness.

Referring to FIGS. 9 and 17, for example, X1 represents a southernmost location of the third pixel opening POP3 and XN represents a northernmost position of the third pixel opening POP3 (e.g., in FIG. 9, XN represents located at a second distance from X1 in the second direction DR2. For example, Y1 represents a southernmost position of the second pixel opening POP2, and YN represents the northernmost position of the second pixel opening POP2 (e.g., in FIG. 9, YN represents located apart from the Y1 in the second direction DR2).

As described above, in the case of the electronic device according to the comparative embodiment, the shielding pattern of the large area may be included. In other words, the slit might not be defined in the shielding pattern included in the display device and the electronic device including the display device according to the comparative embodiment. In this case, measurements of a level of a top surface of the third pixel opening POP3 and the overlapping insulating layer (e.g., the second insulating layer VIA2 of FIG. 8) showed that it varied between about 7.05 micrometers and about 7.22 micrometers. Measurements of the top surface of the insulating layer overlapping the second pixel opening POP2 in the case of the electronic device according to the comparative embodiment showed that it varied between about 7.1 micrometers and about 7.22 micrometers (see REF in dotted line).

In the case of the display device and the electronic device including the display device according to an embodiment of the disclosure, the shielding pattern with the slit defined therein (e.g., the second metal pattern ME2 of FIG. 8) may be included. The slit may be defined to be symmetrical (e.g., refer to FIGS. 15 and 16) with respect to the corresponding opening. In this case, measurements of a level of the top surface of the third pixel opening POP3 and the overlapping insulating layer (e.g., the second insulating layer VIA2 of FIG. 2) showed that it varies between about 7.03 micrometers and about 7.05 micrometers. Measurement of the top surface of the insulating layer overlapping the second pixel opening POP2 in the case of the display device and the electronic device including the display device according to an embodiment of the disclosure showed that it varies between about 7.04 micrometers and about7.08 micrometers (see DD in solid line).

In the case of the display device and the electronic device including the display device according to an embodiment of the disclosure, it can be confirmed that the flatness difference of the emitting part is reduced from about 0.18 to about 0.04 as the shielding pattern with the symmetry slit defined therein. Accordingly, it is possible to improve the flattening difference of the emitting part without increasing the thickness of the insulating layer. In addition, it is possible to further effectively prevent the positioning of the overlay distortion, and the viewing angle characteristics (e.g., degradation of reflectivity, or the like) may be further improved. As a result, the display device (and the electronic device including the display device) with slimming and improved display quality may be provided.

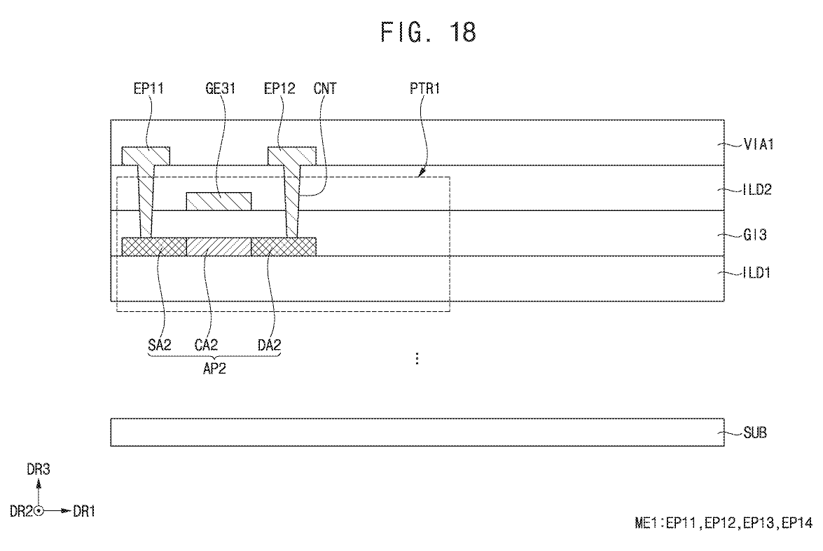

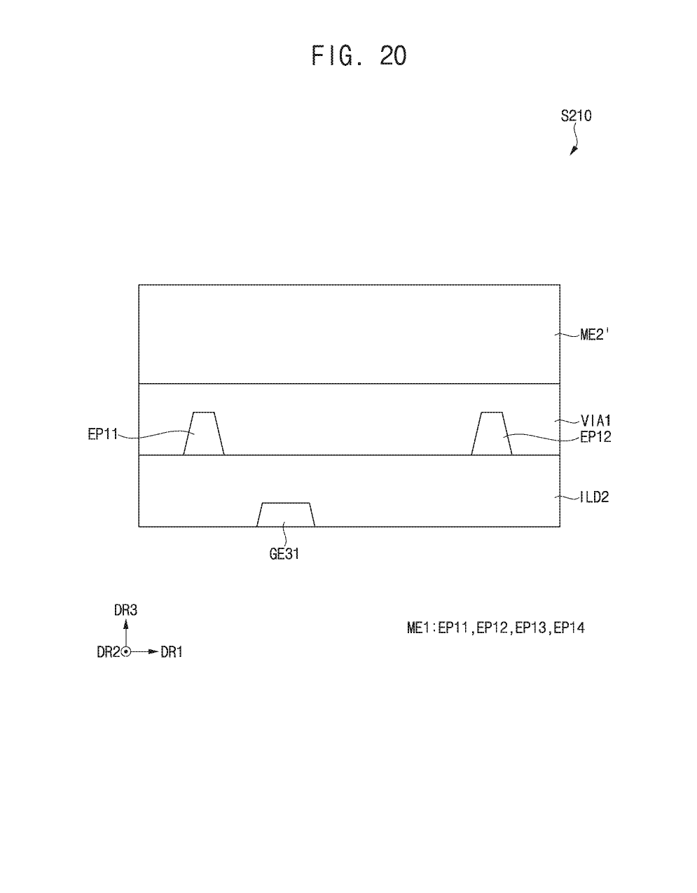

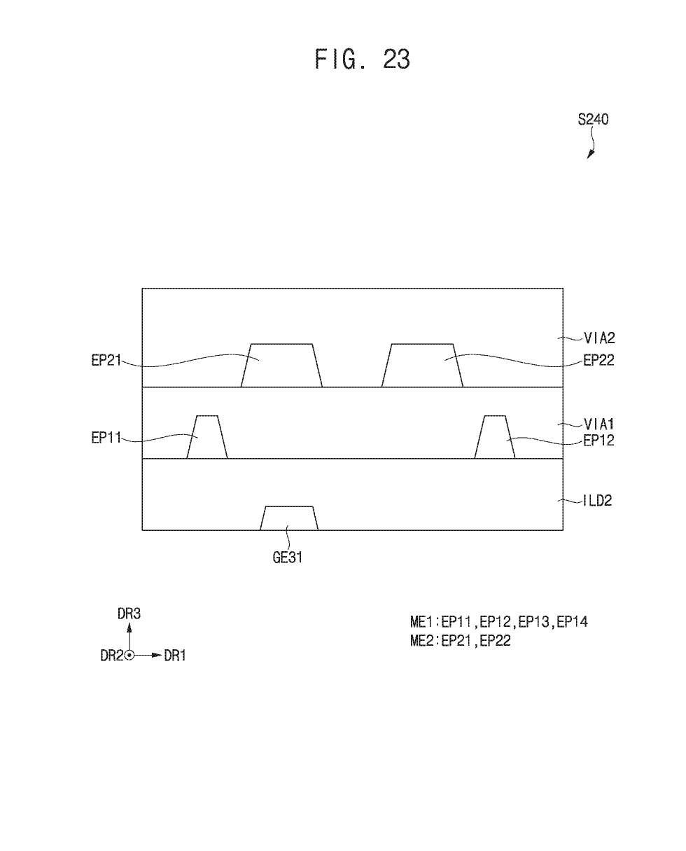

FIGS. 18, 19, 20, 21, 22, 23, and 24 are views illustrating a manufacturing method of the display device and the electronic device including the display device according to an embodiment of the disclosure.

Hereinafter, in description of a manufacturing method of the display device and the electronic device including the display device shown in FIGS. 18, 19, 20, 21, 22, 23, and 24, the same or like elements as those described above with reference to FIGS. 1 to 17 will be omitted or simplified.

Referring to FIGS. 7, 18 and 19, the second active pattern AP2 with N-type dopant, the first third gate electrode GE31 overlapping the second active pattern AP2, and some (or at least one) of the first metal patterns ME1 disposed on the first third gate electrode GE31 and connected through the contact hole to the second active pattern AP2 (e.g., the second source electrode EP11 and the second drain electrode EP12) may be formed on the substrate SUB (S100).

In an embodiment, for example, the second active pattern AP2 may be formed on the first interlayer insulating layer ILD1. The third gate insulating layer GI3 may be formed to cover the second active pattern AP2. The third gate insulating layer GE31 may be formed on the third gate insulating layer GI3. The second interlayer insulating layer ILD2 may be formed to cover the first third gate insulating layer GE31. The first metal pattern ME1 may be formed in the contact hole (e.g., CNT), which is formed through the second interlayer insulating layer ILD2 and the third gate insulating layer GI3. The first metal pattern ME1 may be formed in (or directly on) a same layer as each other. In an embodiment, for example, the first source electrode EP21, the second source electrode EP11, the first drain electrode EP22, and the second drain electrode EP12 may be formed in the same layer. The first via insulating layer VIA1 may be formed to cover the first metal pattern ME1.

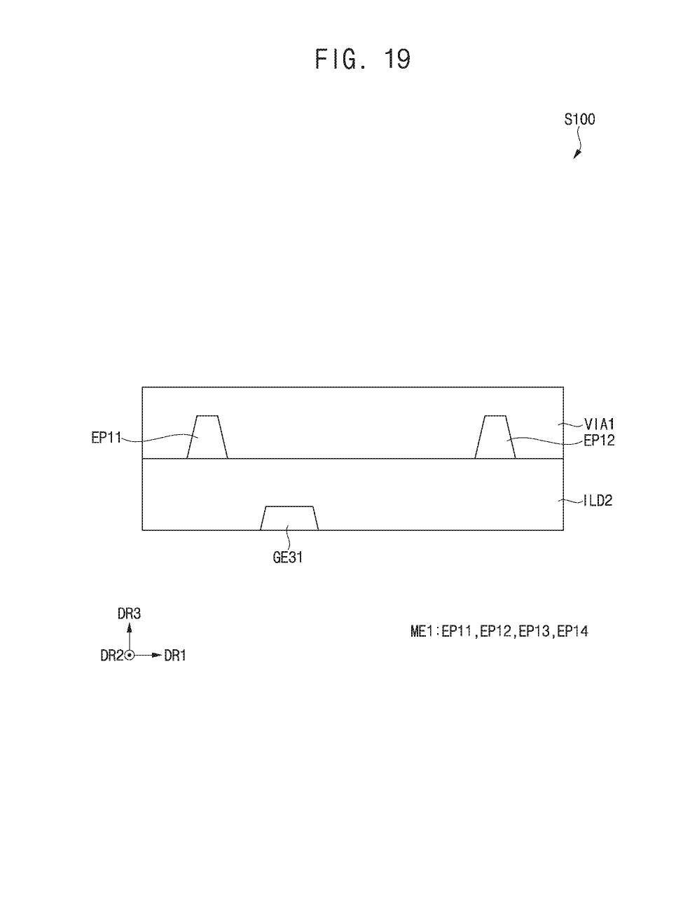

Referring to FIGS. 19, 20, 21, 22, and 23, the second metal pattern ME2 is formed to cover the first third gate electrode GE31 on the first metal patterns ME1, and the slit (e.g., the slit SL of FIG. 15) is formed in the second metal pattern ME2 in the position overlapping the pixel opening (e.g., the POP of FIG. 9) in the third direction DR3 (S210, S220, S230 and S240). The second metal pattern ME2 may shield the NMOS transistor located under the second metal pattern ME2 from the external light.

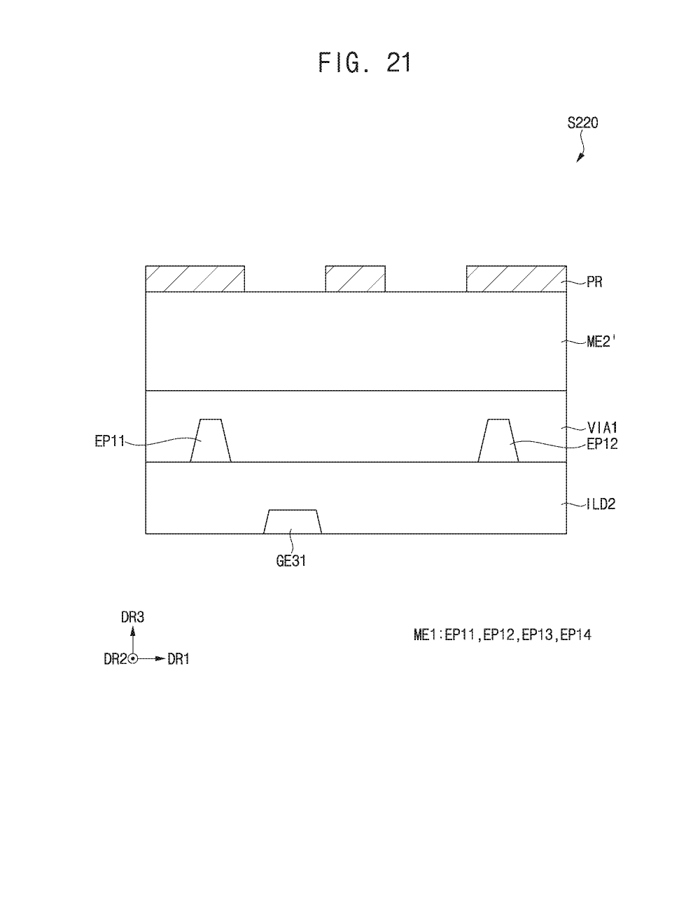

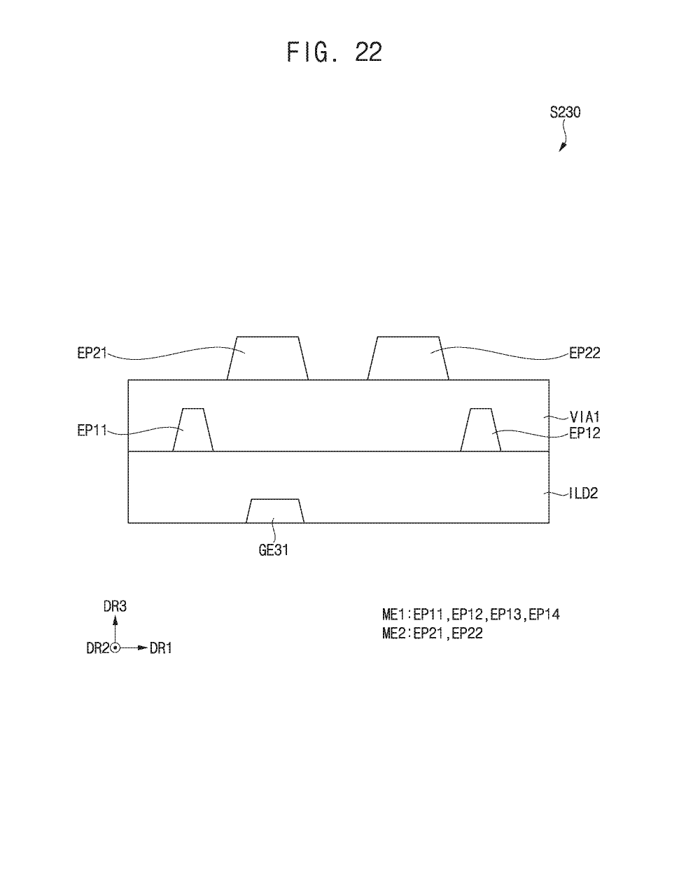

The second preliminary metal layer ME2’ may be formed on the first via insulating layer VIA1 (S210). A portion of the second preliminary metal layer ME2’ may be removed by using photoresist PR so that the slit is formed (e.g., patterning using dry etching). In an embodiment, for example, as shown in FIGS. 21 and 22, the second preliminary metal layer ME2’ at the location where the photoresist PR is disposed, but the disclosure is not limited thereto. In an embodiment, for example, the second preliminary metal layer ME2' at the location where the photoresist PR is not disposed may be removed. Accordingly, the second metal pattern ME2 may be formed (S220, S230). The second via insulating layer VIA2 may be formed on the second metal pattern ME2 (S240).

By forming the slit in the second metal pattern ME2, it is possible to effectively prevent the degradation of the viewing angle characteristics due to the flattening difference of the emitting part, without increasing the thickness of the insulating layer. In other words, the display device and the electronic device including the display device more slimming and with enhanced display quality may be provided.

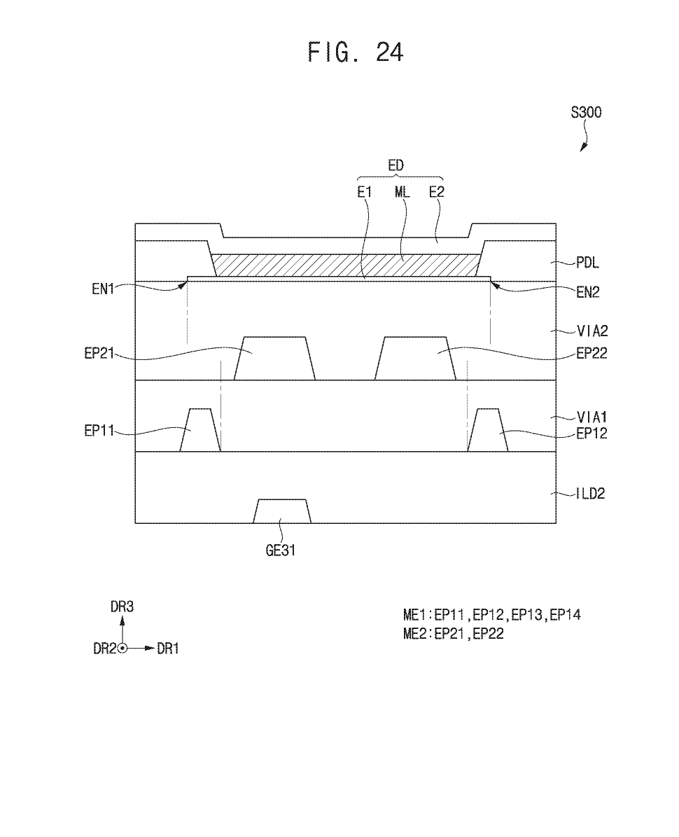

Referring to FIG. 24, a light-emitting element ED including the first electrode E1 and with defined the pixel opening by the pixel defining layer PDL may be formed on the first metal patterns ME1 (S300).

In a cross-sectional view or as shown in FIG. 24, the first electrode E1 may include the first end EN1 and the second end EN2 spaced apart from the first end EN1 in the first direction DR1. In an embodiment, for example, the cross-section may be defined by the first direction DR1 and the third direction DR3. In the removing of the portion of the second preliminary metal layer ME2’ with reference to FIGS. 21 and 22, the portion of the second preliminary metal layer ME2’ where the portions overlapping the ends (e.g., the first end EN1 and the second end EN2) of the first electrode E1 may be removed. Accordingly, the flattening difference of the emitting part by the second metal pattern ME2 may be reduced. In other words, the color asymmetry may be minimized.

In addition, a portion of the second preliminary metal layer ME2' overlapping the first metal patterns ME1 may be removed. Accordingly, the flattening difference of the emitting part due to the first metal patterns ME1 may be reduced. In other words, the color asymmetry may be further minimized.

The display device and the electronic device including the display device according to embodiments may be applied to a computer, a notebook, a mobile phone, a smartphone, a smart pad, a portable media player (“PMP”), a personal digital assistance (“PDA”), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a first type transistor comprising:
a second active pattern disposed on the substrate and doped with an N-type dopant,
a third gate electrode overlapping the second active pattern, and
at least one of first metal patterns disposed on the third gate electrode and connected to the second active pattern through a contact hole;
a light-emitting element disposed on the first metal patterns and comprising a first electrode, wherein a pixel opening is defined by a pixel defining layer; and
a second metal pattern disposed between the first metal patterns and the first electrode, and covering the third gate electrode in a plan view, wherein a slit is defined in the second metal pattern to overlap the pixel opening in the plan view.

2. The display device of claim 1, wherein, in the plan view,
the pixel opening includes a first point, a second point farthest apart from the first point in a first direction, a third point which crosses the first point, a fourth point farthest apart from the third point in a second direction which crosses the first direction,
a minimum distance in the first direction between the first point of the pixel opening and a nearest boundary line most adjacent to the first point in the slit and a minimum distance in the first direction between the second point and a nearest boundary line most adjacent to the second point in the slit are equal to each other, and
a minimum distance in the second direction between the third point of the pixel opening and a nearest boundary line most adjacent to the third point in the slit and a minimum distance in the second direction between the fourth point and a nearest boundary line most adjacent to the fourth point in the slit are equal to each other.

3. The display device of claim 1, wherein, in the plan view, the slit of the second metal pattern defined at positions overlapping the pixel opening are provided in plural.

4. The display device of claim 1, wherein, in a cross-sectional view,
the first electrode includes a first end and a second end spaced apart from the first end in a first direction, and
the second metal pattern is spaced apart from both the first end and the second end.

5. The display device of claim 1, wherein, in a cross-sectional view, in the pixel opening, the second metal pattern and the at least one of the first metal patterns are spaced apart from each other.

6. The display device of claim 1, further comprising:
a second type transistor between the substrate and the first type transistor, and
wherein the second type transistor includes a first active pattern which is doped with a P-type dopant.

7. The display device of claim 6, wherein
the second active pattern includes an oxide semiconductor, and
the first active pattern includes a silicon semiconductor.

8. The display device of claim 1, wherein
the pixel opening includes a first opening of a pixel which emits a first color light, a second opening of the pixel which emits a second color light, different from the first color light, and a third opening of the pixel which emits a third color light, different from both the first and the second color lights,
the second color light is green light, and
the slit is defined to at least partially overlap the second opening in the plan view.

9. The display device of claim 1, wherein the light-emitting element further comprises:
an interlayer disposed on the first electrode in the pixel opening, which is defined by the pixel defining layer; and
a second electrode disposed on the interlayer.

10. The display device of claim 1, further comprising:
an insulating layer disposed between the second metal pattern and the first electrode, and
wherein the insulating layer includes an organic material.

11. A manufacturing method of a display device, the method comprising:
forming a first type transistor on a substrate, wherein the first type transistor comprises: a second active pattern disposed on the substrate and doped with N-type dopant, a third gate electrode overlapping the second active pattern, and at least one of first metal patterns disposed on the third gate electrode and connected to the second active pattern through a contact hole;
forming a second metal pattern on the first metal patterns to cover the third gate electrode in a plan view, wherein a slit is formed through the second metal pattern to overlap a pixel opening in the plan view, and
forming a light-emitting element on the first metal patterns, wherein the light-emitting element includes a first electrode, and the pixel opening is defined by a pixel defining layer.

12. The method of claim 11, wherein the forming the second metal patterns includes:
forming a second preliminary metal layer on a first via insulating layer covering the first metal patterns; and
removing a portion of the second preliminary metal layer by using a photoresist to define the slit.

13. The method of claim 12, wherein
in a cross-sectional view, the first electrode includes a first end and a second end spaced apart in the first direction from the first end, and
in the removing the portion of the second preliminary metal layer, the second preliminary metal layer is removed at positions overlapping the first end and the second end of the first electrode.

14. The method of claim 12, wherein in the removing the portion of the second preliminary metal layer, the second preliminary metal layer is removed at positions overlapping the first metal patterns.

15. An electronic device comprising:
a processor which outputs an image data signal and an input control signal; and
a display device which operates based on the image data signal and the input control signal,
wherein the display device comprises:
a substrate;
a first type transistor comprising:
a second active pattern disposed on the substrate and doped with an N-type dopant,
a third gate electrode overlapping the second active pattern, and
at least one of first metal patterns disposed on the third gate electrode and connected to the second active pattern through a contact hole;
a light-emitting element disposed on the first metal patterns and including a first electrode, wherein a pixel opening is defined by a pixel defining layer; and
a second metal pattern disposed between the first metal patterns and the first electrode, and covering the third gate electrode in a plan view, and a slit is defined in the second metal pattern to overlap the pixel opening in the plan view.

16. The electronic device of claim 15, wherein, in the plan view,
the pixel opening includes a first point, a second point farthest apart from the first point in a first direction, a third point which crosses the first point, a fourth point farthest apart from the third point in a second direction which crosses the first direction,
a minimum distance in the first direction between the first point of the pixel opening and a nearest boundary line most adjacent to the first point in the slit and a minimum distance in the first direction between the second point and a nearest boundary line most adjacent to the second point in the slit are equal to each other, and
a minimum distance in the second direction between the third point of the pixel opening and a nearest boundary line most adjacent to the third point in the slit and a minimum distance in the second direction between the fourth point and a nearest boundary line most adjacent to the fourth point in the slit are equal to each other.

17. The electronic device of claim 15, wherein, in a cross-sectional view,
the first electrode includes a first end and a second end spaced apart from the first end in a first direction, and
the second metal pattern is spaced apart from both the first end and the second end.

18. The electronic device of claim 15, wherein, in a cross-sectional view, in the pixel opening, the second metal pattern and the at least one of the first metal patterns do not overlap each other.

19. The electronic device of claim 15, further comprising:
a second type transistor between the substrate and the first type transistor, and
wherein the second type transistor includes a first active pattern which is doped with a P-type dopant,
wherein the second active pattern includes an oxide semiconductor, and
wherein the first active pattern includes a silicon semiconductor.

20. The electronic device of claim 15, wherein
the pixel opening includes a first opening of a pixel which emits a first color light, a second opening of the pixel which emits a second color light, different from the first color light, and a third opening of the pixel which emits a third color light, different from both the first color light and the second color light,
the second color light is green light, and
the slit is defined to at least partially overlap the second opening in the plan view.
